(19) United States
(12) Patent Application Publication
(10) Pub. No.: US 2026/0088261 A1
(43) Pub. Date: Mar. 26, 2026

(54) STRUCTURAL MEMBER

(71) Applicant: TOTO LTD., Fukuoka (JP)

(72) Inventors: Tatsuya KOGA, Fukuoka (JP); Yasutaka NITTA, Fukuoka (JP)

(73) Assignee: TOTO LTD., Fukuoka (JP)

(21) Appl. No.: 19/314,693

(22) Filed: Aug. 29, 2025

(30) Foreign Application Priority Data
Sep. 26, 2024 (JP) 2024-167275

(51) Int. Cl. H01J 37/32; C23C 14/08; C23C 16/40; C23C 24/04

(52) U.S. Cl. CPC H01J 37/32495; C23C 14/083; C23C 16/405; C23C 24/04

(57) ABSTRACT

Provided is a structural member in which adhesion between the pre-coat layer and the protective film can be enhanced, while the time required to form the pre-coat layer is reduced. The structural member 10 includes a base material 100 and a protective film 200 covering the surface 101 of the base material 100. The protective film 200 includes, as a main component, yttria with an oxygen content lower than the stoichiometric ratio, and the arithmetic mean roughness of the surface of the protective film 200 is 0.65 μm or less.

### CROSS-REFERENCE TO RELATED APPLICATION

This application is based upon and claims the benefit of priority from Japanese Patent Application No. 2024-167275 filed on Sep. 26, 2024, the entire contents of which are incorporated herein by reference.

### FIELD

The present invention relates to a structural member.

### BACKGROUND

Structural members having a protective film on the surface of a base material are used in various fields such as a semiconductor manufacturing apparatus. For example, as disclosed in U.S. Pat. No. 7,767,584, a protective film for protecting a base material from plasma is formed on the surface of the base material forming chamber inner walls of a semiconductor manufacturing apparatus. Oxide ceramics, such as yttria, are often used as protective films.

When processes such as etching are repeated in a semiconductor manufacturing apparatus, by-products generated from the plasma reaction accumulate on the surface of the protective film covering the chamber inner wall. Such by-products must be periodically removed from the surface of the protective film. To facilitate the removal of by-products, pre-coating process is commonly performed in semiconductor manufacturing apparatuses prior to processes such as etching. Pre-coating process refers to a process of forming an Si-containing pre-coat layer in advance on the surface of the protective film.

By-products generated in a process such as etching accumulates on the surface of the pre-coat layer. After completion of the process, the pre-coat layer is removed by an ushing process. At this point, by-products accumulated on the surface of the pre-coat layer are also removed. Since by-products can be removed with minimal physical damage on the surface of the protective film, the functionality of the protective film can be maintained over an extended period.

### SUMMARY

To enhance adhesion between the pre-coat layer and the protective film, the surface of the protective film may be roughened in advance. However, to completely coat the rough surface of the protective film with the pre-coat layer, it is necessary to form a thicker pre-coat layer. As a result, the time required to form the pre-coat layer increases.

The present invention has been made in view of such problems, and an object of the present invention is to provide a structural member in which adhesion between the pre-coat layer and the protective film can be enhanced, while the time required to form the pre-coat layer is reduced.

To solve the above problem, the structural member of the present invention comprises a base material and a protective film covering the surface of the base material. The protective film comprises, as a main component, yttria with an oxygen content lower than the stoichiometric ratio, and the arithmetic mean roughness of the surface is 0.65 μm or less.

By maintaining a relatively smooth surface of the protective film with an arithmetic mean roughness of 0.65 μm or less, it is unnecessary to form a thicker pre-coat layer. This can reduce the time required to form the pre-coat layer.

Furthermore, since the yttria constituting the protective film has an oxygen content lower than the stoichiometric ratio, the surface of the protective film exhibits enhanced reactivity. Therefore, adhesion between the pre-coat layer and the protective film can be effectively achieved while maintaining a relatively smooth surface of the protective film and reducing the time required to form the pre-coat layer as described above.

According to the present invention, a structural member in which adhesion between the pre-coat layer and the protective film is enhanced, while the time required to form the pre-coat layer is reduced can be provided.

### BRIEF DESCRIPTION OF THE DRAWINGS

FIG. 1 schematically illustrates the configuration of a semiconductor manufacturing apparatus;

FIG. 2 schematically illustrates a cross-section of the structural member according to the present embodiment;

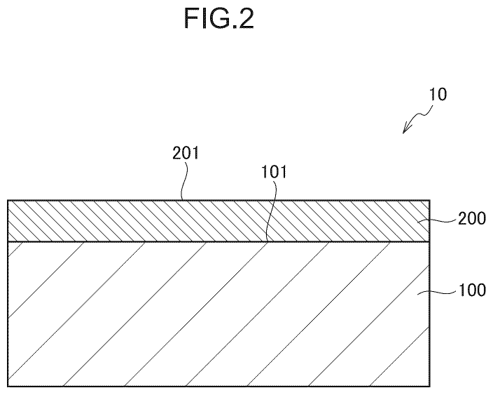

FIGS. 3A, 3B, and 3C illustrate a pre-coat layer; and

FIG. 4 schematically illustrates a cross-section of the structural member according to Comparative Example.

### DETAILED DESCRIPTION

Hereinafter, the present embodiment will be described with reference to attached drawings. For clarity of description, identical reference numerals are used to denote the same elements in all figures, and redundant descriptions are omitted.

The structural member 10 of the present embodiment is used as a member constituting a semiconductor manufacturing apparatus, such as a plasma etching apparatus. Prior to describing the structural member 10, the configuration of the semiconductor manufacturing apparatus will first be described.

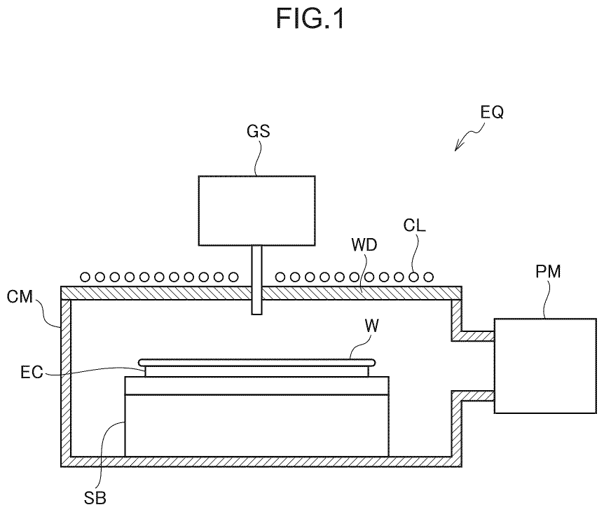

FIG. 1 schematically illustrates the configuration of an etching apparatus EQ, which is an example of a semiconductor manufacturing apparatus. The etching apparatus EQ is a device designed to selectively remove a portion of a film pre-formed on the surface of a base material W, the target of processing, using plasma. The etching apparatus EQ includes a chamber CM, a pump PM, a chuck unit EC, a gas supply unit GS, and a coil CL.

The chamber CM is a container that houses the chuck unit EC and other components. The etching process for the base material W is performed inside the chamber CM. The structural member 10 of the present embodiment is used, for example, as a member constituting the inner wall of the chamber CM.

The pump PM is a device designed to reduce the pressure inside the chamber CM. By evacuating the gas from the chamber CM using the pump PM, the pressure inside the chamber CM is reduced to a level suitable for plasma generation and the etching process.

The chuck unit EC is a device designed to support the base material W from below. An electrostatic chuck that secures the base material W by electrostatic force may be used as the chuck unit EC. The chuck unit EC is provided on a support base SB in the chamber CM.

The gas supply unit GS is a device designed to supply the gas required for plasma generation into the chamber CM. The gas from the gas supply unit GS is supplied into the chamber CM through a top plate WD positioned at the uppermost part of the chamber CM.

The coil CL is designed to generate high-frequency radio waves (RF) between itself and the support base SB, and is positioned above the top plate WD (i.e., outside the chamber CM). The high-frequency radio waves generated by the coil CL pass through the top plate WD and enter the chamber CM. The gas supplied from the gas supply unit GS is ionized by high-frequency radio waves to form plasma, which is used for etching the surface of the base material W.

The structural member 10 of the present embodiment will be described. As described above, the structural member 10 is used, for example, as a member constituting the inner wall of the chamber CM. The structural member 10 comprises a base material 100 and a protective film 200. In the etching apparatus EQ, the surface 201 of the protective film 200 is exposed to the interior of the chamber CM. The protective film 200 is formed to protect the surface 101 of the base material 100 from plasma.

The base material 100 is a member forming the primary portion of the structural member 10. In the present embodiment, the base material 100 is a sintered ceramic body including high-purity aluminum oxide (Al₂O₃), but may be a different type of ceramic sintered body or a non-ceramic material. The surface 101 of the base material 100 is flat in the present embodiment, but may have irregularities or an inclined shape.

The protective film 200 is formed to protect the surface 101 of the base material 100 from plasma as described above. The protective film 200 is formed to cover the entire surface 101 of the base material 100. The thickness of the protective film 200 is appropriately adjusted depending on the duration for which durability is required to be maintained and other factors. In the present embodiment, the protective film 200 has a thickness of 10 μm.

The protective film 200 comprises polycrystalline yttria (yttrium oxide) as a main component. This yttria has an oxygen content lower than the stoichiometric ratio. In other words, when the chemical composition of yttria is represented as Y₂Oₙ, the protective film 200 comprises, as a main component, yttria with an n value less than 3.

The protective film 200 may be provided, for example, by forming an yttria (Y₂O₃) film with a stoichiometric composition in advance and subsequently heating and reducing it in a reduced-pressure environment. The yttria film with a stoichiometric composition may be formed, for example, by a physical vapor deposition (PVD) method, a chemical vapor deposition (CVD) method or an aerosol deposition method.

When processes such as etching are repeated in etching apparatus EG, by-products generated from the plasma reaction accumulate on the surface 201 of the protective film 200 covering the chamber CM inner wall (i.e., the base material 100). Such by-products must be periodically removed from the surface 201 of the protective film 200. To facilitate the removal of by-products, pre-coating process is commonly performed in semiconductor manufacturing apparatuses such as the etching apparatus EQ prior to processes such as etching. Pre-coating process refers to a process of forming an Si-containing pre-coat layer 300 in advance on the surface 201 of the protective film 200.

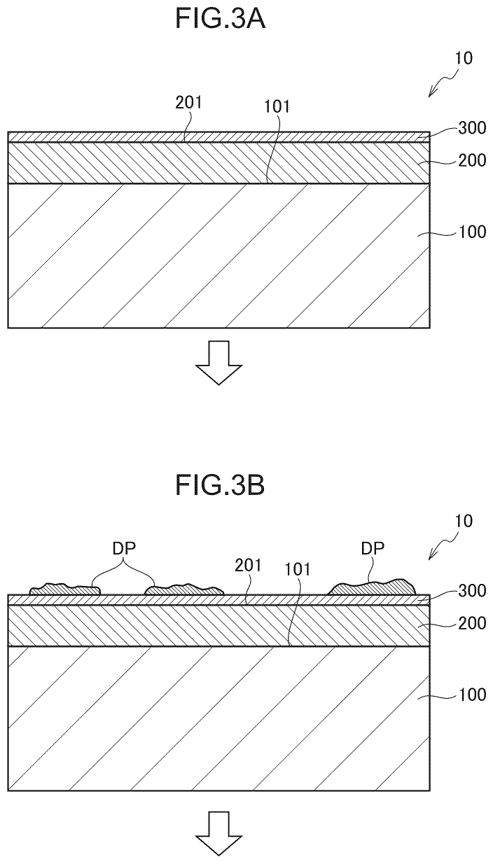

FIG. 3A illustrates the structural member 10 in a state where a pre-coating process has been applied. The entire surface 201 of the protective film 200 is coated with the pre-coat layer 300. The pre-coat layer 300 may be formed, for example, by generating plasma while supplying an Si-containing gas into the chamber CM in the absence of the base material W within the chamber CM.

Subsequently, processes such as etching of the base material W are performed with the surface 201 of the protective film 200 being coated with the pre-coat layer 300. As shown in FIG. 3B, by-products DP generated during the process accumulate on the surface of the pre-coat layer 300.

After the completion of the process, the pre-coat layer 300 is removed by an ushing process using fluorine plasma. At this point, by-products accumulated on the surface of the pre-coat layer 300 are also removed, resulting in the state shown in FIG. 3C. Since by-products DP can be removed with minimal physical damage on the surface 201 of the protective film 200, the functionality of the protective film 200 can be maintained over an extended period.

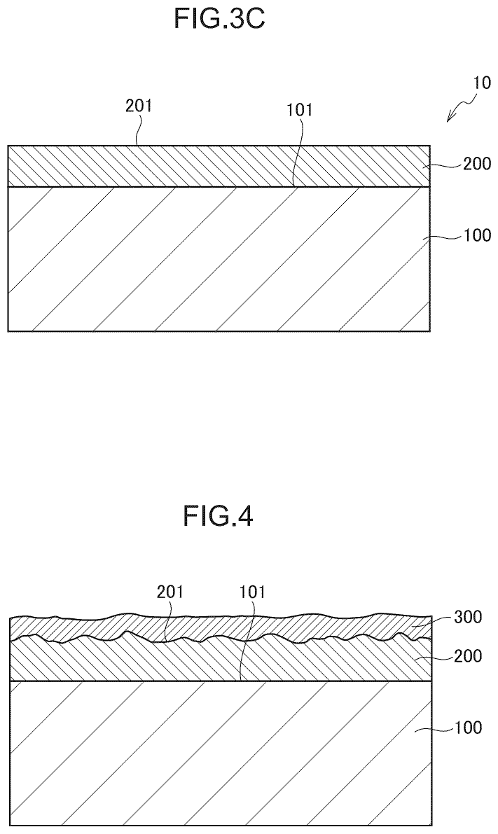

To enhance adhesion between the pre-coat layer 300 and the protective film 200, the surface 201 of the protective film 200 may be roughened prior to the pre-coating process. However, as shown in Comparative Example in FIG. 4, to completely coat the rough surface 201 of the protective film 200 with the pre-coat layer 300 such that the surface 201 is not exposed, it is necessary to form a thicker pre-coat layer 300. As a result, the problem arises that the time required to form the pre-coat layer 300 increases.

Thus, in the present embodiment, the surface 201 of the protective film 200 is formed to be relatively smooth with an arithmetic mean roughness (Ra) of 0.65 μm or less. This surface roughness may be achieved by processes such as polishing of the surface 201 after completion of the formation of the protective film 200. By maintaining a relatively smooth surface 201 as described above, it is unnecessary to form a thicker pre-coat layer 300. This can reduce the time required to form the pre-coat layer 300.

Furthermore, as described above, the yttria constituting the protective film 200 of the present embodiment has an oxygen content lower than the stoichiometric ratio. Thus, the surface 201 of the protective film 200 exhibits enhanced reactivity, and the adhesion strength with the pre-coat layer 300 is increased. As a result, in the present embodiment, adhesion between the pre-coat layer 300 and the protective film 200 can be effectively achieved while maintaining a relatively smooth surface 201 of the protective film 200 and reducing the time required to form the pre-coat layer 300 as described above.

In conventional configurations, to ensure adhesion between the pre-coat layer 300 and the protective film 200, the surface 201 had to be roughened, necessitating a pre-coat layer 300 thickness of 10 μm or greater. In contrast, when the configuration of the present embodiment is adopted, the thickness of the pre-coat layer 300 can be reduced to less than 3 μm.

The arithmetic mean roughness of the surface 201 of the protective film 200 may be set to 0.65 μm or less as described above. When the arithmetic mean roughness is 0.4 μm or less, the time required to form the pre-coat layer 300 can be further reduced. However, to ensure minimal adhesion between the pre-coat layer 300 and the protective film 200, the surface 201 may have an arithmetic mean roughness of 0.01 μm or more.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a base material, and
a protective film covering a surface of the base material, wherein the protective film comprises, as a main component, yttria with an oxygen content lower than the stoichiometric ratio, and
an arithmetic mean roughness of a surface of the protective film is 0.65 μm or less.

2. The structural member according to claim 1, wherein the arithmetic mean roughness of a surface of the protective film is 0.01 μm or more.
